(19) United States
(12) Patent Application Publication
(10) Pub. No.: US 2025/0349578 A1
(43) Pub. Date: Nov. 13, 2025

(54) METHOD OF OPERATING COMPUTING DEVICE COMMUNICATING WITH SEMICONDUCTOR MANUFACTURING EQUIPMENT, AND METHOD OF OPERATING SEMICONDUCTOR MANUFACTURING SYSTEM INCLUDING SEMICONDUCTOR MANUFACTURING EQUIPMENT AND COMPUTING DEVICE

(71) Applicant: Samsung Electronics Co., Ltd., Suwon-si (KR)

(72) Inventors: Bonhyun GU, Suwon-si (KR); Sooyong LEE, Suwon-si (KR); Bongcheol KIM, Suwon-si (KR); Seorim MOON, Suwon-si (KR); Sangjun PARK, Suwon-si (KR); Sangho LEE, Suwon-si (KR)

(73) Assignee: Samsung Electronics Co., Ltd., Suwon-si (KR)

(21) Appl. No.: 18/950,362

(22) Filed: Nov. 18, 2024

(30) Foreign Application Priority Data
May 8, 2024 (KR) 10-2024-0060782

(51) Int. Cl. H01L 21/67; G03F 7/00; H01L 21/66

(52) U.S. Cl. CPC H01L 21/67253; G03F 7/706841; H01L 21/67259; H01L 21/67276; H01L 22/12

(57) ABSTRACT

Disclosed is a method of operating a computing device configured to communicate with semiconductor manufacturing equipment. The method includes receiving layout data of a photomask to be used to manufacture a semiconductor device from the semiconductor manufacturing equipment, the layout data indicating a pattern of the photomask for each position in a distance direction, receiving height data of the semiconductor device from the semiconductor manufacturing equipment, the height data indicating a height of the semiconductor device for each position in the distance direction, generating levelset data based on the layout data, the levelset data indicating an intensity of light passing through the photomask for each position in the distance direction, and generating function model information by training a relationship between the levelset data and the height data.

### CROSS-REFERENCE TO RELATED APPLICATIONS

This application claims priority under 35 U.S.C. § 119 to Korean Patent Application No. 10-2024-0060782 filed on May 8, 2024, in the Korean Intellectual Property Office, the contents of which are incorporated by reference herein in their entireties.

### BACKGROUND

Example Embodiments of the present disclosure described herein relate to semiconductor manufacturing systems, and more particularly, relate to methods of operating a computing device configured to communicate with semiconductor manufacturing equipment and methods of operating a semiconductor manufacturing system including the semiconductor manufacturing equipment and the computing device.

Various semiconductor devices are used in the electronics industry. Semiconductor devices may be implemented with a semiconductor memory element storing data, a semiconductor logic element performing a logic operation, a hybrid semiconductor element supporting memory and logic functions, etc. As the electronics industry becomes more advanced, the demand for characteristics of the semiconductor device is increasing. For example, a higher-reliability, higher-speed, and multi-function semiconductor device is required. To meet the required characteristics, a semiconductor device is highly integrated.

A photolithography process may be used to manufacture a semiconductor device. The photolithography process may include etching a photoresist layer, which is a part of the semiconductor device, with a light passing through a photomask. Because a traveling path of light is capable of being variously changed by refraction or diffraction, it may be difficult to accurately perform the photolithography process in the highly integrated semiconductor device.

### SUMMARY

Some example embodiments of the present disclosure provide methods of operating a computing device configured to communicate with semiconductor manufacturing equipment and methods of operating a semiconductor manufacturing system including the semiconductor manufacturing equipment and the computing device.

According to an example embodiment, a method of operating a computing device, which is configured to communicate with semiconductor manufacturing equipment, includes receiving layout data of a photomask to be used to manufacture a semiconductor device from the semiconductor manufacturing equipment, the layout data indicating a pattern of the photomask for each position in a distance direction, receiving height data of the semiconductor device from the semiconductor manufacturing equipment, the height data indicating a height of the semiconductor device for each position in the distance direction, generating levelset data based on the layout data, the levelset data indicating an intensity of light passing through the photomask for each position in the distance direction, and generating function model information by training a relationship between the levelset data and the height data.

According to an example embodiment, a method of operating a computing device, which is configured to communicate with semiconductor manufacturing equipment, includes receiving layout data of a photomask to be used to manufacture a semiconductor device from the semiconductor manufacturing equipment, receiving height data of the semiconductor device from the semiconductor manufacturing equipment, performing a preprocessing operation based on the layout data and the height data to generate levelset data, the levelset data indicating an intensity of light passing through the photomask for each position in a distance direction, performing a training operation based on the levelset data and the height data to generate function model information, obtaining target height data, and performing an inference operation based on the function model information and the target height data to generate target layout data.

According to an example embodiment, a method of operating a semiconductor manufacturing system, which includes semiconductor manufacturing equipment and a computing device, includes manufacturing, by the semiconductor manufacturing equipment, a semiconductor device by using a photomask corresponding to layout data, measuring, by the semiconductor manufacturing equipment, height data of the semiconductor device, providing, by the semiconductor manufacturing equipment, the layout data to the computing device, providing, by the semiconductor manufacturing equipment, the height data to the computing device, performing, by the computing device, a preprocessing operation based on the layout data and the height data to generate levelset data, the levelset data indicating an intensity of light passing through the photomask for each position in a distance direction, and performing, by the computing device, a training operation based on the levelset data and the height data to generate function model information.

### BRIEF DESCRIPTION OF THE FIGURES

The above and other advantages and features of the present disclosure will become apparent by describing in detail some example embodiments thereof with reference to the accompanying drawings.

FIG. 1 is a diagram describing a semiconductor manufacturing system according to an example embodiment of the present disclosure.

FIG. 2 is a diagram describing an optical device of FIG. 1, according to an example embodiment of the present disclosure.

FIG. 3 is a diagram describing patterns of a photoresist layer of FIG. 1, according to an example embodiment of the present disclosure.

FIG. 4 is a diagram describing a photomask and a semiconductor device of FIG. 1, according to an example embodiment of the present disclosure.

FIG. 5 is a diagram describing a photomask, layout data, and levelset data of FIG. 1, according to an example embodiment of the present disclosure.

FIG. 6 is a block diagram of a computing device according to an example embodiment of the present disclosure.

FIG. 7 illustrates graphs describing levelset data and height data according to an example embodiment of the present disclosure.

FIG. 8 is a graph describing target height data according to an example embodiment of the present disclosure.

FIG. 9 is a flowchart describing a method of operating a semiconductor manufacturing system according to an example embodiment of the present disclosure.

FIG. 10 is a flowchart describing examples of some operations of FIG. 9, according to an example embodiment of the present disclosure.

FIG. 11 is a flowchart describing examples of some operations of FIG. 9, according to an example embodiment of the present disclosure.

FIG. 12 is a flowchart describing a method of operating a computing device according to an example embodiment of the present disclosure.

### DETAILED DESCRIPTION

When the terms “about” or “substantially” are used in this specification in connection with a numerical value, it is intended that the associated numerical value includes a manufacturing tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Below, some example embodiments of the present disclosure will be described in detail and clearly to such an extent that one skilled in the art carries out example embodiments of the present disclosure easily.

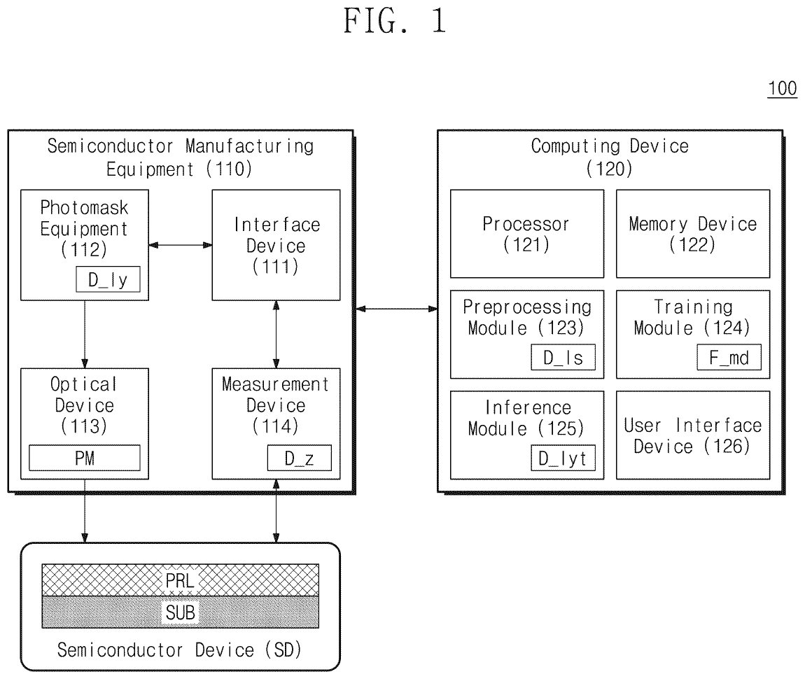

FIG. 1 is a diagram describing a semiconductor manufacturing system according to an example embodiment of the present disclosure. Referring to FIG. 1, a semiconductor manufacturing system 100 may manufacture a semiconductor device SD. The semiconductor device SD may be used in the electronics industry. The semiconductor device SD may be implemented with a semiconductor memory element storing data, a semiconductor logic element performing a logic operation, a hybrid semiconductor element supporting memory and logic functions, etc.

In some example embodiments, the semiconductor device SD may be manufactured by using a photolithography process. The semiconductor device SD may include a semiconductor substrate SUB, and a photoresist layer PRL disposed on the semiconductor substrate SUB. The photolithography process may include etching the photoresist layer PRL, which is a part of the semiconductor device SD, with a light passing through a photomask PM (e.g., with an exposed or irradiated light).

In some example embodiments, the photoresist layer PRL of the semiconductor device SD may be etched in the shape of plural layers with different heights. For example, the semiconductor device SD may be a vertical NAND (VNAND)-based flash memory device. The semiconductor device SD may be designed in a three-dimensional structure. The photoresist layer PRL may be etched in the shape of a stair pattern to implement plural word lines of the VNAND-based flash memory device. The stair pattern may refer to a pattern in which the height of the etched photoresist layer PRL varies with a physical position.

The semiconductor manufacturing system 100 may include semiconductor manufacturing equipment 110 and a computing device 120. The semiconductor manufacturing equipment 110 may directly manufacture the semiconductor device SD under control of the computing device 120. The semiconductor manufacturing equipment 110 may include an interface device 111, photomask equipment 112, an optical device 113, and a measurement device 114.

The interface device 111 may provide an interface between the computing device 120, the photomask equipment 112, and the measurement device 114. For example, the interface device 111 may receive an electrical signal for controlling the semiconductor manufacturing equipment 110 from the computing device 120. Under control of the computing device 120, the interface device 111 may drive the semiconductor manufacturing equipment 110 or may provide data managed by the semiconductor manufacturing equipment 110 to the computing device 120.

The photomask equipment 112 may manage the photomask PM based on layout data D_ly. The layout data D_ly may include information for designing the photomask PM. For example, the layout data D_ly may indicate a pattern of the photomask PM for each position in a distance direction (e.g., a direction parallel to the semiconductor substrate SUB). The photomask PM may include a pattern designed depending on the layout data D_ly. The photomask PM may include a bar pattern or a space pattern for each position in the distance direction. The bar pattern may block a light exposed or irradiated from the optical device 113 to the photoresist layer PRL. The space pattern may pass the light exposed or irradiated from the optical device 113 to the photoresist layer PRL.

The photomask equipment 112 may manufacture the photomask PM based on the layout data D_ly and may provide the photomask PM to the optical device 113 depending on an automated process. In some example embodiments, the photomask equipment 112 may receive the photomask PM from a separate external device, may identify the photomask PM based on the layout data D_ly, and may provide the identified photomask PM to the optical device 113. The photomask equipment 112 may provide the layout data D_ly to the computing device 120 through the interface device 111.

The optical device 113 may be provided with the photomask PM from the photomask equipment 112. The optical device 113 may etch the photoresist layer PRL of the semiconductor device SD by performing the photolithography process by using the photomask PM.

The measurement device 114 may measure height data D_z of the semiconductor device SD. The height data D_z may indicate the height of the semiconductor device SD measured for each position in the distance direction. The height may indicate the thickness of the semiconductor device SD measured in a height direction perpendicular to the semiconductor substrate SUB. The height of the semiconductor device SD may vary with how much the photoresist layer PRL is etched by the light of the optical device 113. The measurement device 114 may provide the height data D_z to the computing device 120 through the interface device 111.

The computing device 120 may control the semiconductor manufacturing equipment 110. The computing device 120 may be an electronic device (e.g., a personal computer (PC), a laptop, a tablet PC, or a smartphone) configured to process a variety of information. The computing device 120 may include a processor 121, a memory device 122, a preprocessing module 123, a training module 124, an inference module 125, and a user interface device 126.

The processor 121 may control overall operations of the computing device 120. The processor 121 may load data stored in the memory device 122 and may process the loaded data. For example, the processor 121 may be implemented with a central processing unit (CPU), a graphics processing unit (GPU), a neural processing device, etc. The processor 121 may support machine learning. The machine learning may include a training operation and an inference operation.

The memory device 122 may operate as a main memory of the processor 121. For example, the memory device 122 may be implemented with a volatile memory device such as a dynamic random access memory (DRAM) or a static random access memory (SRAM).

The preprocessing module 123 may perform a preprocessing operation based on the layout data D_ly and the height data D_z. The preprocessing operation may refer to an operation of revising the contents of data or changing a type (or format) of data, so as to be appropriate for the machine learning.

For example, the preprocessing module 123 may receive the layout data D_ly from the semiconductor manufacturing equipment 110. The preprocessing module 123 may transform the layout data D_ly into levelset data D_ls. The levelset data D_ls may indicate the intensity of light passing through the photomask PM for each position. Because the intensity of light has a correlation with the etched degree of the photoresist layer PRL, the levelset data D_ls may be more appropriate for the machine learning than the layout data D_ly.

The preprocessing module 123 may transform types of the levelset data D_ls and the height data D_z into types capable of being used for the machine learning. For example, the preprocessing module 123 may transform the types of the levelset data D_ls and the height data D_z by rasterization and may provide the preprocessed levelset data D_ls and the preprocessed height data D_z to the training module 124.

The training module 124 may train the relationship between the levelset data D_ls and the height data D_z based on the preprocessed levelset data D_ls and the preprocessed height data D_z and may generate function model information F_md based on the trained relationship. The operation of generating the function model information F_md based on the trained relationship may be referred to as a “training operation”. The function model information F_md may include a function in which a level value of the levelset data D_ls is used as an input and a height value of the height data D_z is used as an output.

For example, the training module 124 may generate the function model information F_md by training the relationship between the levelset data D_ls and the height data D_z by a deep learning model, updating parameters constituting initial function model information based on the trained relationship, and optimizing or further tuning the updated parameters.

The inference module 125 may receive the function model information F_md from the training module 124. The inference module 125 may receive information for setting target height data from the user interface device 126. The target height data may be set by the user or an application program executed by the user and may indicate a height of a semiconductor device for each position in the distance direction.

The inference module 125 may generate target levelset data based on the target height data and the function model information F_md and may generate target layout data based on the target levelset data. The target layout data may indicate a pattern of a target photomask which is expected to generate a semiconductor device having a physical standard corresponding to the target height data. The operation of generating the target layout data based on the target height data and the function model information F_md may be referred to as an “inference operation”.

The target layout data generated by the inference operation may reflect optical proximity correction (OPC). Because a traveling path of light is variously changed by refraction or diffraction, the pattern of the photomask PM may be different from the pattern of the photoresist layer PRL. The optical proximity correction may mean correcting the pattern of the photomask PM in consideration of the refraction or diffraction of the light such that the etched shape of the photoresist layer PRL is similar to the designed shape. Because the target layout data are inferred by the function model information F_md training the relationship between the actual pattern of the photomask PM and the measured height data D_z, the target layout data may indicate the pattern of the photomask PM to which the optical proximity correction is reflected.

The user interface device 126 may provide an interface between the computing device 120 and the user. The user interface device 126 may receive information for setting the target height data from the user. The user interface device 126 may provide the target height data set by the user to the inference module 125 or may provide the target height data set through the application program executed by the user to the inference module 125. For example, the user interface device 126 may be implemented with a display device, a touchscreen, a mouse, a keyboard, a microphone, a speaker, etc.

In some example embodiments, at least some of the functions of the preprocessing module 123, the training module 124, and the inference module 125 may be implemented by software. For example, the memory device 122 may be a non-transitory computer-readable storage medium which stores at least some of the functions of the preprocessing module 123, the training module 124, and the inference module 125 as computer executable instructions. The processor 121 may implement at least some of the functions of the preprocessing module 123, the training module 124, and the inference module 125 by executing the instructions stored in the memory device 122.

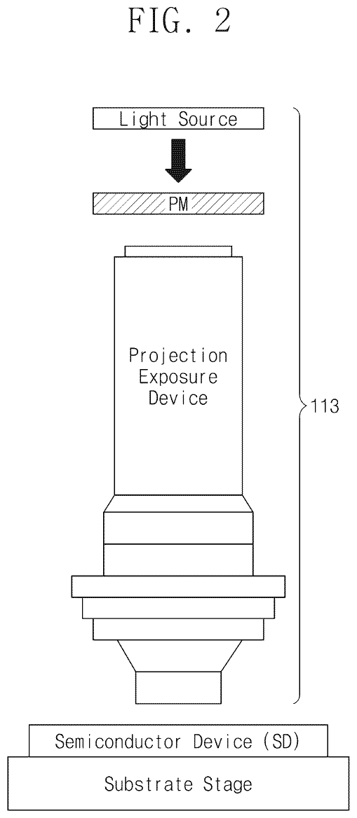

FIG. 2 is a diagram describing an optical device of FIG. 1, according to an example embodiment of the present disclosure. Referring to FIGS. 1 and 2, the optical device 113 may receive the photomask PM from the photomask equipment 112. The photomask PM may include a bar pattern or a space pattern depending on a distance. The optical device 113 may perform the photolithography process of the semiconductor device SD disposed on a substrate stage. The optical device 113 may include a light source, the photomask PM, and a projection exposure device.

The light source may output a light. For example, the light source may be an ultraviolet light source, such as a KrF light source having a wavelength of 234 nm or about 234 nm, an ArF light source having a wavelength of 193 nm or about 193 nm, or an extreme ultraviolet (EUV) light source.

The photomask PM may block or pass the light output from the light source depending on the pattern. The photomask PM may include a bar pattern or a space pattern for each position in the distance direction. The bar pattern may block the light. The space pattern may pass the light. The light passing through the space pattern may travel to the projection exposure device along the path changed by the refraction or diffraction.

The projection exposure device may be provided with the light passing through the space pattern of the photomask PM. The projection exposure device may match patterns printed on the semiconductor device SD and patterns of the photomask PM and may project the light passing through the photomask PM to the semiconductor device SD. Accordingly, patterns corresponding to the photomask PM may be printed on the semiconductor device SD. The patterns printed on the semiconductor device SD may include a stair pattern.

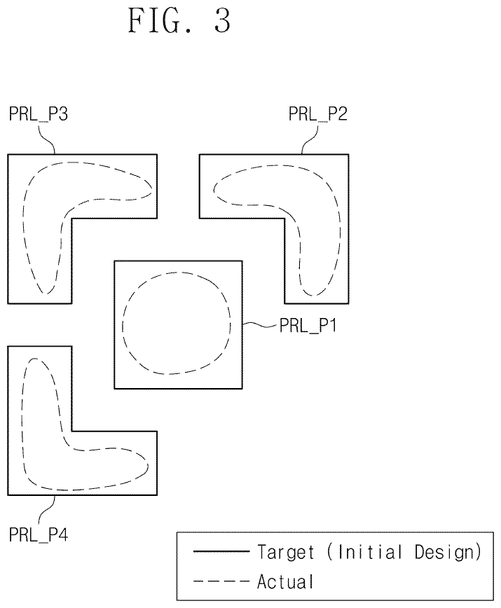

FIG. 3 is a diagram describing patterns of a photoresist layer of FIG. 1, according to an example embodiment of the present disclosure. An example of patterns of the photoresist layer PRL of the semiconductor device SD that the optical device 113 manufactures by using the initially designed photomask PM will be described with reference to FIGS. 1 and 3.

The photoresist layer PRL etched by the photolithography process may include first to fourth photolithography layer patterns PRL_P1 to PRL_P4. Each of the first to fourth photolithography layer patterns PRL_P1 to PRL_P4 illustrated may indicate a boundary with which the height of the photoresist layer PRL varies, when the photoresist layer PRL is viewed in a direction perpendicular to the semiconductor substrate SUB.

The initially designed photomask PM may be manufactured under the assumption that the light travels straightly, without consideration of the refraction or diffraction of light. The first to fourth photolithography layer patterns PRL_P1 to PRL_P4 which the user designs as a target are illustrated by a solid line. The pattern illustrated by a solid line may be the same as the pattern of the photomask PM used in the example of FIG. 3.

The first to fourth photolithography layer patterns PRL_P1 to PRL_P4 actually manufactured are illustrated by a dashed line. The traveling path of light may change by refraction or diffraction. As the size of the semiconductor device SD is scaled down and the semiconductor device SD is highly integrated, the influence of the refraction or diffraction on the photolithography process is increasing. For example, the patterns illustrated by a solid line may be different from the patterns illustrated by a dashed line.

To obtain the patterns illustrated by a solid line in the manufactured semiconductor device SD, there may be a need to correct the pattern of the photomask PM. To correct the pattern of the photomask PM to obtain patterns manufactured to be similar to designed patterns in the photolithography process may be referred to as “optical proximity correction (OPC)”. As the semiconductor device SD is designed in a three-dimensional structure and is highly integrated, nowadays, it may be difficult to design the photomask PM through the application of the optical proximity correction (OPC).

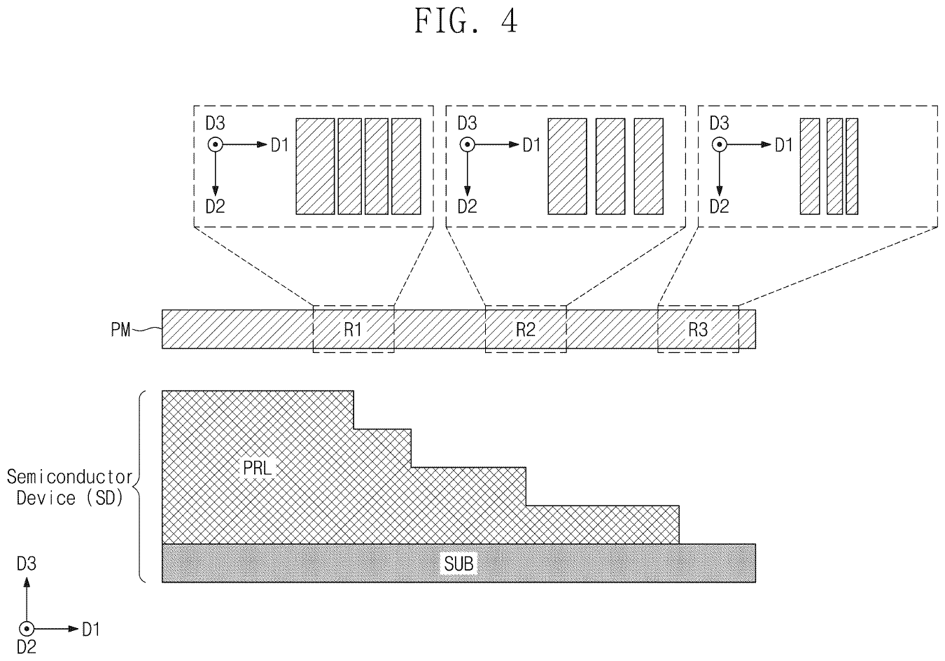

FIG. 4 is a diagram describing a photomask and a semiconductor device of FIG. 1, according to an example embodiment of the present disclosure. An example of the photomask PM and the semiconductor device SD will be described with reference to FIGS. 1 and 4.

For better understanding of the present disclosure, a first direction D1, a second direction D2, and a third direction D3 are mentioned. The first direction D1 may be parallel to the semiconductor substrate SUB. The first direction D1 may be also referred to as a “distance direction”. The second direction D2 may be parallel to the semiconductor substrate SUB and may be perpendicular to the first direction D1. The third direction D3 may be perpendicular to the semiconductor substrate SUB. The third direction D3 may be also referred to as a “height direction”.

The semiconductor device SD may be designed in a three-dimensional structure. The semiconductor device SD may include the semiconductor substrate SUB and the photoresist layer PRL. The photoresist layer PRL may be disposed on the semiconductor substrate SUB. The photoresist layer PRL may have a stair pattern. The stair pattern may refer to a pattern in which the height of the semiconductor device SD measured in the third direction D3 varies with a position in the first direction D1 as the intensity of light passing through the photomask PM varies with the position in the first direction D1.

The photomask PM may be designed to include a bar pattern or a space pattern along the first direction D1. The bar pattern may block the light. The space pattern may pass the light. The light passing through the space pattern may be refracted or diffracted and may then etch the photoresist layer PRL of the semiconductor device SD. The degree to which the photoresist layer PRL is etched may vary with the intensity of refracted or diffracted light.

First to third regions R1 to R3 indicate positions of the photomask PM in the first direction D1. The photomask PM and the semiconductor device SD may be disposed in parallel in the first direction D1. In other words, the photomask PM and the semiconductor device SD may be disposed such that positions thereof overlap each other in the first direction D1.

In the first region R1, the frequency of the bar pattern of the photomask PM may be high. The intensity of light passing through the photomask PM may be weak. The etched degree may be relatively small at the corresponding position of the photoresist layer PRL. The thickness of the photoresist layer PRL may be relatively large.

In the second region R2, the frequency of the bar pattern of the photomask PM may decrease compared to the first region R1. The intensity of light passing through the photomask PM in the second region R2 may be stronger than the intensity of light passing through the photomask PM in the first region R1. The etched degree may increase at the corresponding position of the photoresist layer PRL. The thickness of the photoresist layer PRL may decrease.

In the third region R3, the frequency of the bar pattern of the photomask PM may decrease compared to the second region R2. The intensity of light passing through the photomask PM may be stronger than the intensity of light passing through the photomask PM in the second region R2. The etched degree may further increase at the corresponding position of the photoresist layer PRL. The thickness of the photoresist layer PRL may further decrease.

For better understanding of the present disclosure, the example of the pattern of the photomask PM is described, but the illustrated pattern is not intended to limit the scope of the present disclosure. In the photomask PM, the number of bar patterns, the number of space patterns, widths of bar patterns, and widths of space patterns may variously change due to various factors such as a wavelength of a light, the size of the semiconductor device SD, and a pattern at an adjacent position.

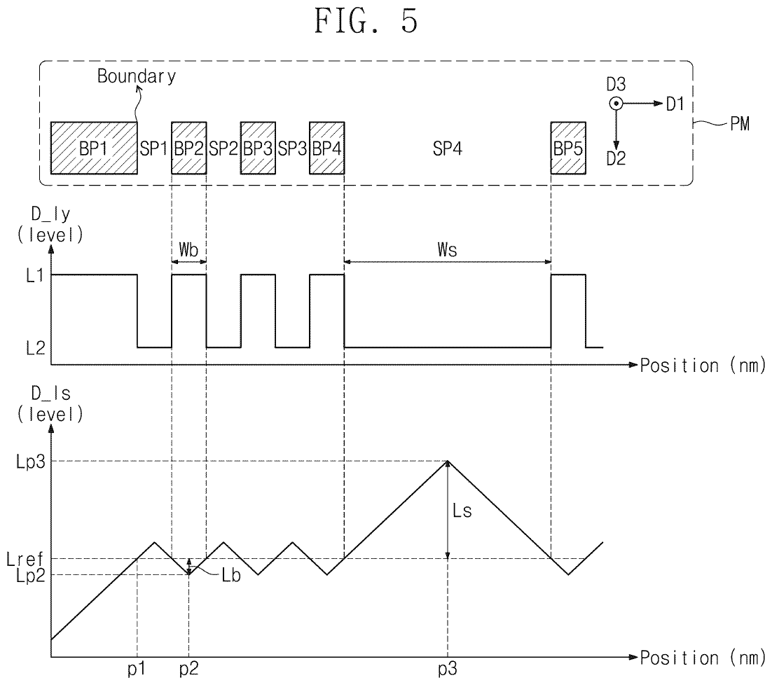

FIG. 5 is a diagram describing a photomask, layout data, and levelset data of FIG. 1, according to an example embodiment of the present disclosure. Examples of the photomask PM, the layout data D_ly, and the levelset data D_ls will be described with reference to FIGS. 1 and 5. The photomask PM, the layout data D_ly, and the levelset data D_ls may be disposed such that positions in the first direction D1 overlap each other.

Referring to FIG. 5, the photomask PM may include a first bar pattern BP1, a first space pattern SP1, a second bar pattern BP2, a second space pattern SP2, a third bar pattern BP3, a third space pattern SP3, a fourth bar pattern BP4, a fourth space pattern SP4, and a fifth bar pattern BP5 sequentially in the first direction D1. The first to fifth bar patterns BP1 to BP5 may block a light. The first to fourth space patterns SP1 to SP4 may pass a light. Each of the patterns BP1, SP1, BP2, SP2, BP3, SP3, BP4, SP4, and BP5 of the photomask PM may have the width of an arbitrary size in the first direction D1.

The layout data D_ly may indicate a layout for designing the photomask PM. Referring to the graph of the layout data D_ly, the horizontal axis represents a position in the distance direction in units of nanometer (nm), and the vertical axis represents a value of a level. The layout data D_ly may have a first level value L1 corresponding to the bar patterns BP1 to BP5 or a second level value L2 corresponding to the space patterns SP1 to SP4, depending on a position in the first direction D1.

Because the layout data D_ly are expressed by using two level values L1 and L2, when the photoresist layer PRL is etched to include plural layers with different heights, it may be difficult to directly train the relationship between the layout data D_ly and the height. To make the training operation of the machine learning easy, a preprocessing technique for transforming the layout data D_ly into data of a format associated with the height may be desired.

The preprocessing module 123 of the present disclosure may generate the levelset data D_ls based on a levelset conversion operation of the layout data D_ly. The levelset data D_ls may indicate the predicted (or calculated) intensity of light passing through the photomask PM based on the layout data D_ly, for each position in the first direction D1.

Referring to the graph of the levelset data D_ls, the horizontal axis represents a position in the distance direction in units of nanometer (nm), and the vertical axis represents a value of a level. The levelset data D_ls may indicate the intensity of light, which is calculated based on the bar patterns BP1 to BP5, the space patterns SP1 to SP4, and the widths of the bar patterns BP1 to BP5 and the space patterns SP1 to SP4.

For example, referring to a first position p1, the first position p1 may indicate the boundary between the first bar pattern BP1 and the first space pattern SP1. The levelset data D_ls may have a reference level value Lref at the first position p1. The reference level value Lref may indicate the critical or reference intensity of light for etching the photoresist layer PRL, but the scope of the present disclosure is not necessarily limited thereto.

For example, referring to a second position p2, the second position p2 may indicate the center of the second bar pattern BP2. At the second position p2, the levelset data D_ls may have a level value Lp2 obtained by decreasing the reference level value Lref as much as a bar level value Lb (e.g., decreasing the reference level value Lref by a bar level value Lb), which is proportional to a width Wb of the second bar pattern BP2. The light of the level value Lp2 may be incapable of etching the photoresist layer PRL. The photoresist layer PRL may be etched by the light refracted or diffracted from the space patterns SP1 and SP2 adjacent to each other at the second position p2.

For example, referring to a third position p3, the third position p3 may indicate the center of the fourth space pattern SP4. At the third position p3, the levelset data D_ls may have a level value Lp3 obtained by increasing the reference level value Lref as much as a space level value Ls (e.g., increasing the reference level value Lref by a space level value Ls), which is proportional to a width Ws of the fourth space pattern SP4. The light of the level value Lp3 may be capable of etching the photoresist layer PRL strongly. The height of the photoresist layer PRL may be the lowest at the third position p3.

Because the intensity of light described by the levelset data D_ls has the direct correlation with the height data D_z of the semiconductor device SD, the levelset data D_ls may be more appropriate for the training operation than the layout data D_ly.

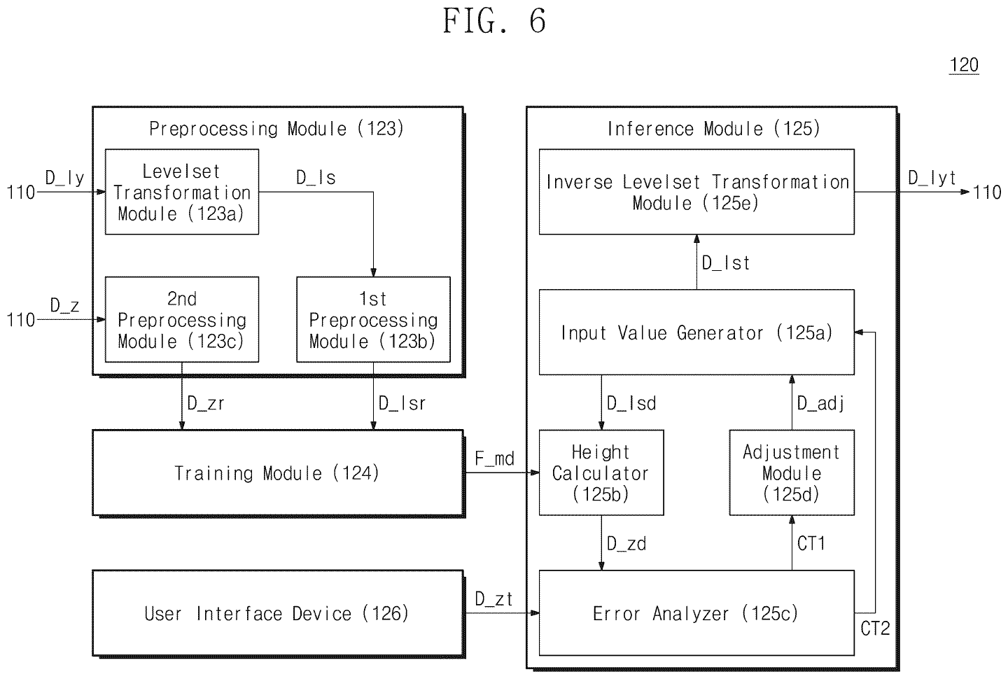

Because the levelset data D_ls indicates the intensity of light associated with the position in the first direction D1, the levelset data D_ls may be information of a two-dimensional type. As in the above description, because the height data D_z indicates the height of the semiconductor device SD associated with the position in the first direction D1, the height data D_z may be information of a two-dimensional type. Preprocessing operations for transforming the levelset data D_ls and the height data D_z into information of a one-dimensional type may be further desired for the training operation. The preprocessing operations will be described in detail with reference to FIG. 6.

FIG. 6 is a block diagram of a computing device according to an example embodiment of the present disclosure. Referring to FIG. 6, the computing device 120 may communicate with the semiconductor manufacturing equipment 110. The semiconductor manufacturing equipment 110 and the computing device 120 may correspond to the semiconductor manufacturing equipment 110 and the computing device 120 of FIG. 1, respectively. The computing device 120 may include the preprocessing module 123, the training module 124, the inference module 125, and the user interface device 126.

The preprocessing module 123 may communicate with the semiconductor manufacturing equipment 110 and the training module 124. The preprocessing module 123 may include a levelset transformation module 123a, a first preprocessing module 123b, and a second preprocessing module 123c.

The levelset transformation module 123a may receive the layout data D_ly from the semiconductor manufacturing equipment 110. The layout data D_ly may indicate a pattern of a photomask. The levelset transformation module 123a may generate the levelset data D_ls based on the levelset transformation operation of the layout data D_ly. The levelset transformation operation may refer to an operation of generating the levelset data D_ls based on the bar patterns and the space patterns described by the layout data D_ly. Because the levelset data D_ls have the direct correlation with the height data D_z, the levelset data D_ls may be more appropriate for the training operation than the layout data D_ly.

The first preprocessing module 123b may receive the levelset data D_ls from the levelset transformation module 123a. The first preprocessing module 123b may generate preprocessed levelset data D_lsr of the one-dimensional type, based on a first-type preprocessing operation of the levelset data D_ls. Because the levelset data D_ls and the height data D_z share a position in the first direction D1, information about a position may not be needed in the training operation. The preprocessed levelset data D_lsr may be generated by the first-type preprocessing operation in the form of a one-dimensional vector or a pixel by extracting a level value of the levelset data D_ls, for each of positions spaced apart from each other as much as a given interval (e.g., for each of positions at regular intervals). For example, the first-type preprocessing operation may include a first rasterization operation.

The second preprocessing module 123c may receive the height data D_z from the semiconductor manufacturing equipment 110. The second preprocessing module 123c may generate preprocessed height data D_zr of a one-dimensional type, based on a second-type preprocessing operation of the height data D_z. As described in the first-type preprocessing operation, information about a position may not be needed in the training operation. The preprocessed height data D_zr may be generated by the second-type preprocessing operation in the form of a one-dimensional vector or a pixel by extracting a height value of the height data D_z, for each of positions spaced apart from each other as much as a given interval (e.g., the same as the given interval used for extraction in the first-type preprocessing operation). For example, the second-type preprocessing operation may include a second rasterization operation.

The training module 124 may communicate with the preprocessing module 123 and the inference module 125. The training module 124 may receive the preprocessed levelset data D_lsr and the preprocessed height data D_zr from the preprocessing module 123. The training module 124 may train the relationship between the level value and the height value based on the preprocessed levelset data D_lsr and the preprocessed height data D_zr and may generate the function model information F_md based on the trained relationship. The operation in which the training module 124 generates the function model information F_md may be also referred to as a “training operation”.

The function model information F_md may include a function trained by the deep learning model. The trained function may be a function in which the preprocessed levelset data D_lsr (or the level value of the levelset data D_ls) is used as an input and the preprocessed height data D_zr (or the height value of the height data D_z) is used as an output.

The inference module 125 may communicate with the training module 124, the user interface device 126, and the semiconductor manufacturing equipment 110. The inference module 125 may receive the function model information F_md from the training module 124.

The inference module 125 may receive target height data D_zt from the user interface device 126 directly or through any other application program. The target height data D_zt may be set by the user or application program managing the user interface device 126 and may indicate a height of a target semiconductor device according to a position in the distance direction. An inference target of the inference module 125 may be target layout data D_lyt for designing a target photomask to be used to manufacture the target semiconductor device with the standard of the target height data D_zt.

The inference module 125 may include an input value generator 125a, a height calculator 125b, an error analyzer 125c, an adjustment module 125d, and an inverse levelset transformation module 125e.

The input value generator 125a may generate dummy levelset data D_lsd. The dummy levelset data D_lsd may be data temporarily generated in the inference operation. As in the preprocessed levelset data D_lsr, the dummy levelset data D_lsd may have a one-dimensional type.

In an initial loop (e.g., an epoch or iteration of the inference operation), the input value generator 125a may generate the dummy levelset data D_lsd as an initial value. In a subsequent loop, the input value generator 125a may generate the dummy levelset data D_lsd based on adjustment data D_adj received from the adjustment module 125d.

The height calculator 125b may receive the dummy levelset data D_lsd from the input value generator 125a. The height calculator 125b may receive the function model information F_md from the training module 124. The height calculator 125b may calculate dummy height data D_zd based on the function model information F_md and the dummy levelset data D_lsd. For example, the height calculator 125b may input the dummy levelset data D_lsd to the function of the function model information F_md and may obtain the dummy height data D_zd output by the function. As in the preprocessed height data D_zr, the dummy height data D_zd may have a one-dimensional type.

The error analyzer 125c may receive the target height data D_zt from the user interface device 126 directly or through any other application program. The error analyzer 125c may preprocess and use the target height data D_zt (e.g., may transform and use the target height data D_zt to have a type capable of being applied to the function model information F_md). The error analyzer 125c may receive the dummy height data D_zd from the height calculator 125b. The error analyzer 125c may determine whether an error of the dummy height data D_zd is optimized (e.g., in a tolerance range), based on the dummy height data D_zd and the target height data D_zt. The error may indicate a difference of a value obtained by the inference operation and a target value.

In some example embodiments, the error analyzer 125c may determine whether an error of the dummy height data D_zd is optimized (e.g., in the tolerance range), by referring to previous height data obtained in a previous loop together.

The error analyzer 125c may provide a first control signal CT1 to the adjustment module 125d in response to determining that the error of the dummy height data D_zd is not optimized (e.g., not in the tolerance range). The first control signal CT1 may include information (e.g., a sign, a magnitude, etc. of a value of an analyzed error) which indicates that the error is not optimized (e.g., not in the tolerance range) and is used to correct the dummy levelset data D_lsd.

The adjustment module 125d may generate the adjustment data D_adj based on the first control signal CT1. The adjustment data D_adj may include information which is used to adjust the dummy levelset data D_lsd. The input value generator 125a may adjust the dummy levelset data D_lsd based on the adjustment data D_adj. The input value generator 125a may continuously perform the inference operation of a next loop based on the adjusted dummy levelset data D_lsd.

Referring again to the error analyzer 125c, the error analyzer 125c may provide a second control signal CT2 to the input value generator 125a in response to determining that the error of the dummy height data D_zd is optimized (e.g., in the tolerance range). The second control signal CT2 may indicate that the error is optimized (e.g., in the tolerance range).

The input value generator 125a may determine the dummy levelset data D_lsd as target levelset data D_lst, based on the second control signal CT2. The input value generator 125a may provide the target levelset data D_lst to the inverse levelset transformation module 125e.

The inverse levelset transformation module 125e may transform the one-dimensional type of the target levelset data D_lst into a two-dimensional type. The target levelset data D_lst converted into the two-dimensional type may indicate the intensity of light passing through the photomask for each position in the distance direction. The inverse levelset transformation module 125e may generate the target layout data D_lyt based on an inverse levelset transformation operation, which transforms the target levelset data D_lst into the two-dimensional type.

That is, the inverse levelset transformation module 125e may perform an inverse operation to the first-type preprocessing operation of the first preprocessing module 123b and may then perform an inverse operation to the levelset transformation operation of the levelset transformation module 123a.

The inverse levelset transformation module 125e may provide the target layout data D_lyt to the semiconductor manufacturing equipment 110. The semiconductor manufacturing equipment 110 may obtain the target photomask based on the target layout data D_lyt and may manufacture the target semiconductor device by using the target photomask. The height data measured from the target semiconductor device may be substantially similar to the target height data D_zt. Because the target photomask is inferred based on the function model information F_md, the target photomask may include a pattern to which the optical proximity correction (OPC) is applied.

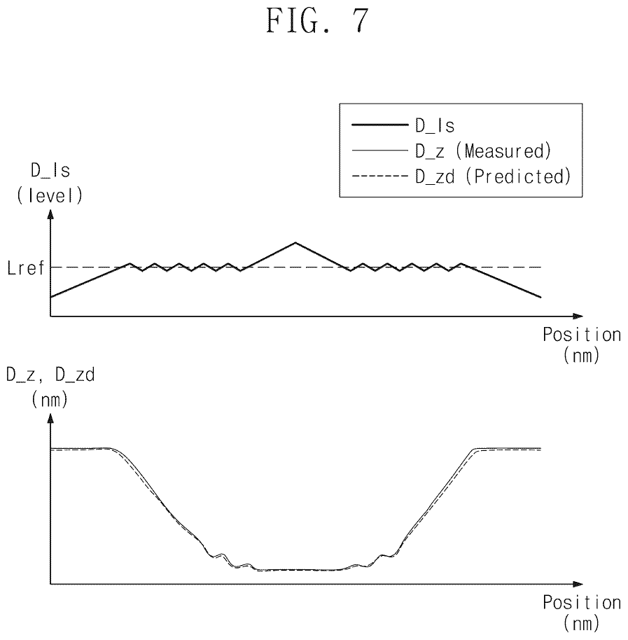

FIG. 7 illustrates graphs describing levelset data and height data according to an example embodiment of the present disclosure. Examples of waveforms of the levelset data D_ls, the height data D_z, and the dummy height data D_zd will be described with reference to FIGS. 6 and 7. Waveforms are illustrated such that positions in the distance direction overlap each other.

The waveform of the levelset data D_ls may correspond to the levelset data D_ls output by the levelset transformation module 123a. The waveform of the height data D_z may correspond to the height data D_z which are measured by the semiconductor manufacturing equipment 110 and are input to the second preprocessing module 123c. The dummy height data D_zd may correspond to the dummy height data D_zd output by the height calculator 125b and determined (e.g., predicted by an interference operation) as having an error optimized (e.g., as being in the tolerance range) by the error analyzer 125c, when the target height data D_zt are the same as the height data D_z.

Referring to the waveform of the levelset data D_ls, the horizontal axis represents a position in the distance direction in units of nanometer (nm), and the vertical axis represents a level value. The waveform of the levelset data D_ls may have a level value exceeding the reference level value Lref at some positions.

Referring to the waveform of the height data D_z and the waveform of the dummy height data D_zd, the horizontal axis represents a position in the distance direction in units of nanometer (nm), and the vertical axis represents a height in the height direction in units of nanometer (nm).

The height value of the height data D_z may have a higher value at a position where the level value of the levelset data D_ls is smaller than the reference level value Lref. Thus, the height value of the height data D_z may be the smallest at a position where the level value of the levelset data D_ls is the greatest or at a position close thereto. The height data D_z and the levelset data D_ls may have a correlation. The waveform of the dummy height data D_zd may be considerably similar to the waveform of the height data D_z.

The inference module 125 may generate the target layout data D_lyt corresponding to the dummy height data D_zd. The semiconductor manufacturing equipment 110 may manufacture the target semiconductor device by using the target photomask with the patterns described by the target layout data D_lyt. The measured height data of the target semiconductor device may be considerably or substantially similar to the dummy height data D_zt.

In other words, the higher reliability of the function model information F_md and the inference operation may be verified by performing the inference operation by using the target height data D_zt set to be the same as the measured height data D_z.

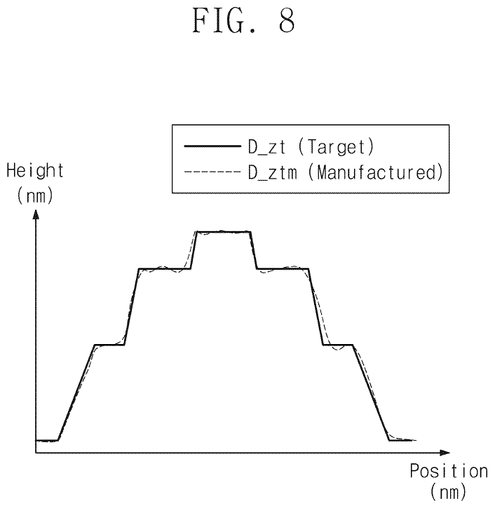

FIG. 8 is a graph describing target height data according to an example embodiment of the present disclosure. Referring to FIGS. 6 and 8, the waveform of the target height data D_zt and the waveform of manufactured target height data D_ztm are illustrated. The horizontal axis represents a position in the distance direction in units of nanometer (nm), and the vertical axis represents a height in the height direction in units of nanometer (nm).

The waveform of the target height data D_zt may correspond to the target height data D_zt provided by the user interface device 126. Unlike the example of FIG. 6 in which the reliability of the function model information F_md and the inference operation is verified, the target height data D_zt may be arbitrarily set to be different from the height data D_z. The waveform of the manufactured target height data D_ztm may indicate a measured height of a target semiconductor device which the semiconductor manufacturing equipment 110 manufactures by using the target photomask corresponding to the target layout data D_lyt.

The waveform of the target height data D_zt may be considerably or substantially similar to the waveform of the manufactured target height data D_ztm. Even though the target height data D_zt are arbitrarily set through the user interface device 126, the target layout data D_lyt of the target photomask corresponding to the arbitrarily set standard may be generated with higher reliability, and the target semiconductor device corresponding to the standard arbitrarily set by the target photomask may be manufactured.

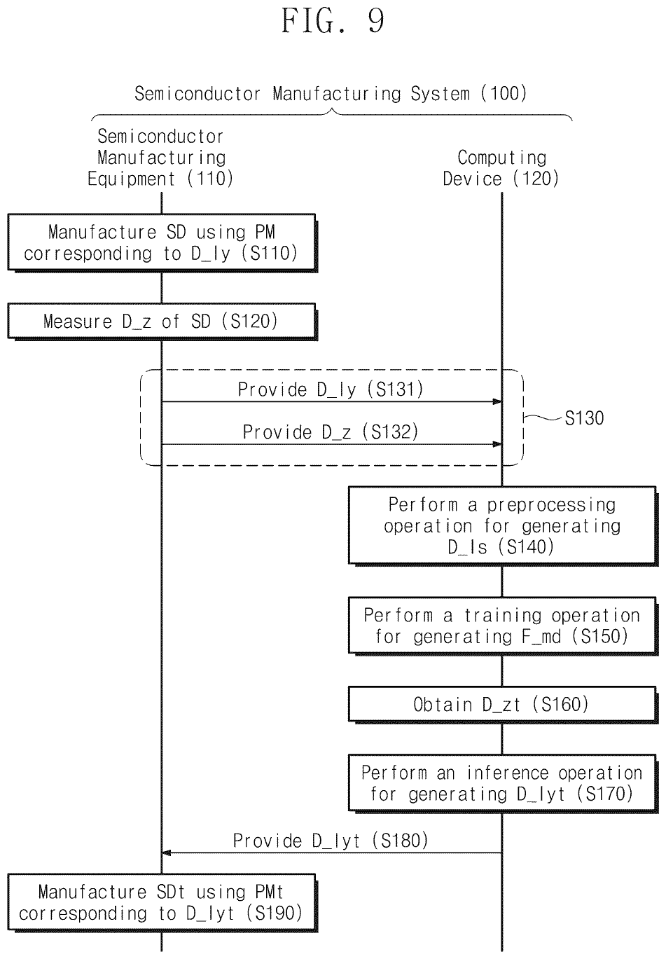

FIG. 9 is a flowchart describing a method of operating a semiconductor manufacturing system according to an example embodiment of the present disclosure. Referring to FIG. 9, the semiconductor manufacturing system 100 may include the semiconductor manufacturing equipment 110 and the computing device 120.

In operation S110, the semiconductor manufacturing equipment 110 may manufacture the semiconductor device SD by using the photomask PM corresponding to the layout data D_ly. The layout data D_ly may indicate the pattern of the photomask PM for each position in the distance direction. The pattern of the photomask PM may include a bar pattern blocking a light or a space pattern passing a light, depending on a position. The manufacturing of the semiconductor device SD may include the photolithography process which is based on the light passing through the space pattern.

In operation S120, the semiconductor manufacturing equipment 110 may measure the height data D_z of the semiconductor device SD. The height data D_z may indicate the height of the semiconductor device SD for each position in the distance direction.

In operation S130, the semiconductor manufacturing equipment 110 may provide information for the preprocessing operation to the computing device 120. Operation S130 may include operation S131 and operation S132. In operation S131, the semiconductor manufacturing equipment 110 may provide the layout data D_ly to the computing device 120. In operation S132, the semiconductor manufacturing equipment 110 may provide the height data D_z to the computing device 120.

In operation S140, the computing device 120 may perform the preprocessing operation to generate the levelset data D_ls. The preprocessing operation may include transforming the format of the layout data D_ly and the height data D_z so as to be used in the training operation. The levelset data D_ls may indicate the intensity of light passing through the photomask PM for each position in the distance direction.

In operation S150, the computing device 120 may perform the training operation to generate the function model information F_md. The function model information F_md may include a function in which a level value of the levelset data D_ls is used as an input and a height value of the height data D_z is used as an output.

In operation S160, the computing device 120 may obtain the target height data D_zt. For example, the computing device 120 may receive the target height data D_zt from a user interface device. The target height data D_zt may be set by the user or application program managing the user interface device and may indicate the height of a target semiconductor device SDt for each position in the distance direction.

In operation S170, the computing device 120 may perform the inference operation to generate the target layout data D_lyt. The target layout data D_lyt may indicate the pattern (e.g., the bar or space pattern) of a target photomask PMt for manufacturing the target semiconductor device SDt with the standard of the target height data D_zt (e.g., manufacturing the target semiconductor device SDt having the target height data D_zt).

In operation S180, the computing device 120 may provide the target layout data D_lyt to the semiconductor manufacturing equipment 110.

In operation S190, the semiconductor manufacturing equipment 110 may manufacture the target semiconductor device SDt by using the target photomask PMt corresponding to the target layout data D_lyt. For example, the semiconductor manufacturing equipment 110 may manufacture the target photomask PMt based on the target layout data D_lyt. The semiconductor manufacturing equipment 110 may manufacture the target semiconductor device SDt by etching a photoresist layer of the target semiconductor device SDt by using the target photomask PMt. The measured height data of the manufactured target semiconductor device SDt may be considerably or substantially similar to the target height data D_zt in operation S160.

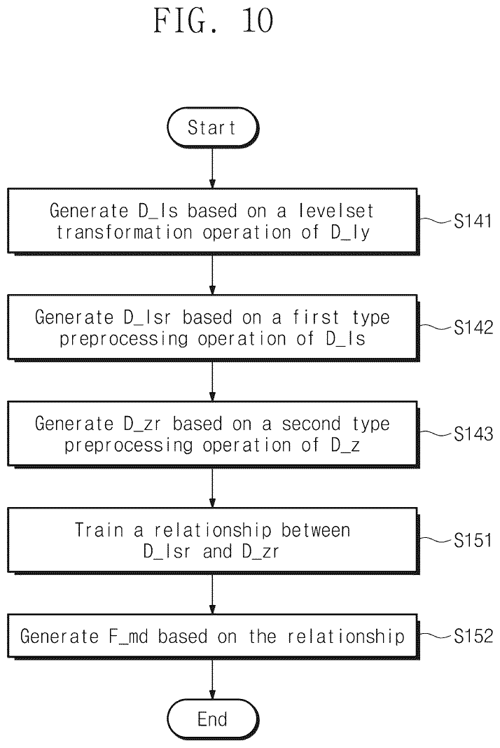

FIG. 10 is a flowchart describing examples of some operations of FIG. 9, according to an example embodiment of the present disclosure. Referring to FIGS. 9 and 10, operation S141, operation S142, and operation S143 may correspond to operation S140. Operation S151 and operation S152 may correspond to operation S150.

In operation S141, the computing device 120 may generate the levelset data D_ls based on the levelset transformation operation of the layout data D_ly. The levelset transformation operation may refer to an operation of generating a level value according to a distance, based on the bar pattern and the space pattern described by the layout data D_ly.

In operation S142, the computing device 120 may generate the preprocessed levelset data D_lsr based on the first-type preprocessing operation of the levelset data D_ls. The levelset data D_ls may have a two-dimensional type in association with a position in the distance direction and a level value. The preprocessed levelset data D_lsr obtained by the first-type preprocessing operation may have a one-dimensional type in association with a level value. For example, the first-type preprocessing operation may include the first rasterization operation.

In operation S143, the computing device 120 may generate the preprocessed height data D_zr based on the second-type preprocessing operation of the height data D_z. The height data D_z may have a two-dimensional type in association with a position in the distance direction and a height in the height direction. The preprocessed height data D_zr obtained by the second-type preprocessing operation may have a one-dimensional type in association with a height. For example, the second-type preprocessing operation may include the second rasterization operation.

In operation S151, the computing device 120 may train or learn the relationship between the preprocessed levelset data D_lsr and the preprocessed height data D_zr. In operation S152, the computing device 120 may generate the function model information F_md based on the relationship (e.g., the trained relationship or learned relationship).

In some example embodiments, the computing device 120 may generate the function model information F_md by training the relationship between level values of the preprocessed levelset data D_lsr and height values of the preprocessed height data D_zr by using the deep learning model, updating parameters constituting initial function model information based on the trained relationship, and optimizing or further tuning the updated parameters.

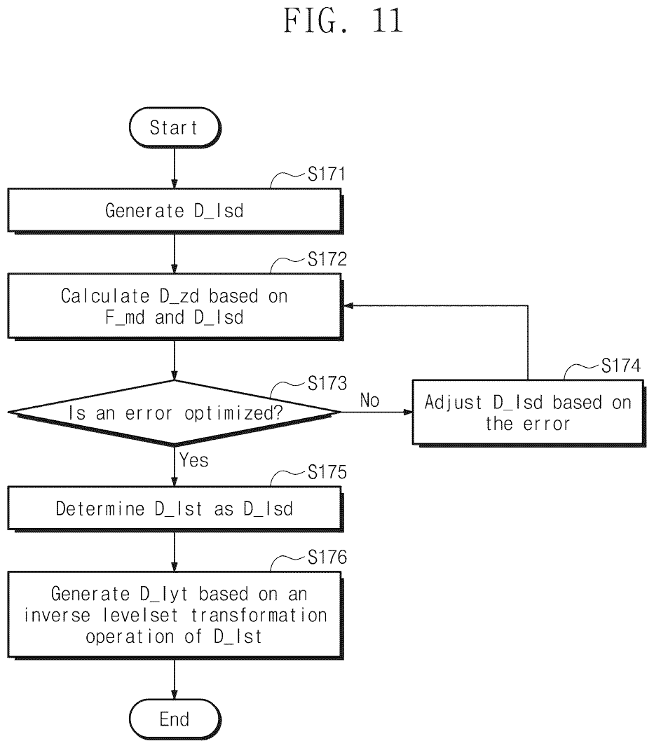

FIG. 11 is a flowchart describing examples of some operations of FIG. 9, according to an example embodiment of the present disclosure. Referring to FIGS. 9 and 11, operation S171, operation S172, operation S173, operation S174, operation S175, and operation S176 may correspond to operation S170.

In operation S171, the computing device 120 may generate the dummy levelset data D_lsd. The dummy levelset data D_lsd in operation S171 may be also referred to as an “initial input value” in an initial loop of the inference operation.

In operation S172, the computing device 120 may calculate the dummy height data D_zd based on the function model information F_md and the dummy levelset data D_lsd. For example, the computing device 120 may input the dummy levelset data D_lsd to the function described by the function model information F_md and may obtain the dummy height data D_zd as an output of the function.

In operation S173, the computing device 120 may determine whether an error of the dummy height data D_zd is optimized (e.g., is in the tolerance range). For example, the computing device 120 may determine whether the error of the dummy height data D_zd is optimized (e.g., is in the tolerance range), based on the target height data D_zt and the dummy height data D_zd. In some example embodiments, the computing device 120 may determine whether the error is optimized (e.g., is in the tolerance range), by further considering previous dummy height data of a previous loop. When it is determined that the error of the dummy height data D_zd is not optimized (e.g., is not in the tolerance range), the computing device 120 may perform operation S174.

In operation S174, the computing device 120 may adjust the dummy levelset data D_lsd based on the error. The computing device 120 may further perform operation S172 based on the adjusted dummy levelset data (e.g., the adjustment data D_adj) instead of the dummy levelset data D_lsd. The additional inference of operation S172 may be also referred to as an “operation of a next loop”.

Returning to operation S173, when it is determined that the error of the dummy height data D_zd is optimized (e.g., is in the tolerance range), the computing device 120 may perform operation S175.

In operation S175, the computing device 120 may determine, as the target levelset data D_lst, the dummy levelset data D_lsd corresponding to the dummy height data D_zd with the optimized error (e.g., the adjustment data D_adj having an error within a tolerance range).

In operation S176, the computing device 120 may generate the target layout data D_lyt based on the inverse levelset transformation operation of the target levelset data D_lst. The inverse levelset transformation operation may be the inverse operation to the levelset transformation operation in operation S141 of FIG. 10.

In some example embodiments, the computing device 120 may transform the target levelset data D_lst of the one-dimensional type into the target levelset data D_lst of the two-dimensional type before the execution of the inverse levelset transformation operation. The transformation may correspond to the inverse operation to the first-type preprocessing operation in operation S142 of FIG. 10.

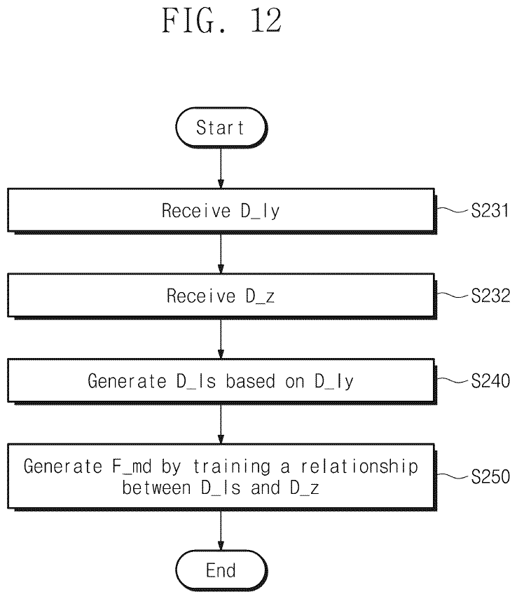

FIG. 12 is a flowchart describing a method of operating a computing device according to an example embodiment of the present disclosure. Referring to FIG. 12, a computing device may communicate with semiconductor manufacturing equipment.

In operation S231, the computing device may receive the layout data D_ly from the semiconductor manufacturing equipment. The layout data D_ly may indicate a pattern of a photomask, which is used for the semiconductor manufacturing equipment to manufacture a semiconductor device, for each position in the distance direction.

In operation S232, the computing device may receive the height data D_z from the semiconductor manufacturing equipment. The height data D_z may indicate the measured height of the semiconductor device manufactured by the semiconductor manufacturing equipment, for each position in the distance direction.

In operation S240, the computing device may generate the levelset data D_ls based on the layout data D_ly. The levelset data D_ls may indicate the intensity of light passing through the photomask for each position in the distance direction.

In operation S250, the computing device may generate the function model information F_md by training or learning the relationship between the levelset data D_ls and the height data D_z. The function model information F_md may include a function in which a level value of the levelset data D_ls is used as an input and a height value of the height data D_z is used as an output. The operation of generating the function model information F_md may be referred to as a “training operation”. The function model information F_md may be used in a subsequent inference operation.

According to some example embodiments of the present disclosure, methods of operating a computing device communicating with semiconductor manufacturing equipment and methods of operating a semiconductor manufacturing system including the semiconductor manufacturing equipment and the computing device are provided.

Also, methods of operating a computing device to train the relationship between the thickness of the etched photoresist layer and the pattern of the photomask by applying levelset data indicating the intensity of exposed or irradiated light to machine learning and methods of operating a semiconductor manufacturing system are provided.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the present disclosure has been described with reference to some example embodiments thereof, it will be apparent to those of ordinary skill in the art that various changes and modifications may be made thereto without departing from the spirit and scope of the present disclosure as set forth in the following claims.

What is claimed is:

1. A method of operating a computing device, which is configured to communicate with semiconductor manufacturing equipment, the method comprising:
receiving layout data of a photomask to be used to manufacture a semiconductor device from the semiconductor manufacturing equipment, the layout data indicating a pattern of the photomask for each position in a distance direction;
receiving height data of the semiconductor device from the semiconductor manufacturing equipment, the height data indicating a height of the semiconductor device for each position in the distance direction;
generating levelset data based on the layout data, the levelset data indicating an intensity of light passing through the photomask for each position in the distance direction; and
generating function model information by training a relationship between the levelset data and the height data.

2. The method of claim 1, wherein
the pattern of the photomask includes a bar pattern blocking the light or a space pattern passing the light for each position in the distance direction, and
the layout data have a first level value corresponding to the bar pattern or a second level value corresponding to the space pattern, for each position in the distance direction.

3. The method of claim 2, wherein the levelset data includes
a reference level value at a first position of a boundary between the bar pattern and the space pattern,
a level value obtained by decreasing the reference level value by a bar level value at a second position corresponding to a center of the bar pattern, the bar level value being proportional to a width of the bar pattern, and
a level value obtained by increasing the reference level value by a space level value at a third position corresponding to a center of the space pattern, the space level value being proportional to a width of the space pattern.

4. The method of claim 1, wherein
the semiconductor device includes a semiconductor substrate and a photoresist layer on the semiconductor substrate, and
the height of the semiconductor device varies with a degree of etching of the photoresist layer.

5. The method of claim 1, wherein the function model information includes a function in which a level value of the levelset data is used as an input and a height value of the height data is used as an output.

6. The method of claim 1, further comprising:
receiving information for setting target height data from a user interface device; and
generating target layout data corresponding to the target height data, based on the function model information and the target height data.

7. The method of claim 6, wherein
the target height data are set by a user or an application program configured to manage the user interface device and indicate a height of a target semiconductor device for each position in the distance direction, and
the target layout data indicate a pattern of a target photomask for manufacturing the target semiconductor device.

8. The method of claim 6, wherein the generating the target layout data includes:
generating first dummy levelset data;
calculating first dummy height data based on the function model information and the first dummy levelset data;
determining whether an error of the first dummy height data is in a tolerance range, based on the first dummy height data and the target height data; and
adjusting the first dummy levelset data to generate second dummy levelset data, in response to determining that the error of the first dummy height data is not in the tolerance range.

9. The method of claim 8, wherein the generating the target layout data further includes:
calculating second dummy height data based on the function model information and the second dummy levelset data;
determining whether an error of the second dummy height data is in the tolerance range, based on the second dummy height data and the target height data;
determining the second dummy levelset data as target levelset data in response to determining that the error of the second dummy height data is in the tolerance range; and
generating the target layout data based on the target levelset data.

10. The method of claim 6, further comprising:
providing the target layout data to the semiconductor manufacturing equipment.

11. The method of claim 1, further comprising:
before generating the function model information, generating preprocessed levelset data of a one-dimensional type, based on a first-type preprocessing operation of the levelset data; and
before generating the function model information, generating preprocessed height data of the one-dimensional type, based on a second-type preprocessing operation of the height data,
wherein the generating the function model information includes generating the function model information by training the relationship between the levelset data and the height data based on the preprocessed levelset data and the preprocessed height data.

12. The method of claim 11, wherein
the first-type preprocessing operation includes a first rasterization operation, and
the second-type preprocessing operation includes a second rasterization operation.

13. A method of operating a computing device, which is configured to communicate with semiconductor manufacturing equipment, the method comprising:
receiving layout data of a photomask to be used to manufacture a semiconductor device from the semiconductor manufacturing equipment;
receiving height data of the semiconductor device from the semiconductor manufacturing equipment;
performing a preprocessing operation based on the layout data and the height data to generate levelset data, the levelset data indicating an intensity of light passing through the photomask for each position in a distance direction;
performing a training operation based on the levelset data and the height data to generate function model information;
obtaining target height data; and
performing an inference operation based on the function model information and the target height data to generate target layout data.

14. The method of claim 13, wherein the performing the preprocessing operation includes:
generating the levelset data based on a levelset transformation operation of the layout data;
generating preprocessed levelset data of a one-dimensional type, based on a first-type preprocessing operation of the levelset data; and
generating preprocessed height data of the one-dimensional type, based on a second-type preprocessing operation of the height data.

15. The method of claim 14, wherein the performing the training operation includes:
training a relationship between the preprocessed levelset data and the preprocessed height data; and
generating the function model information based on the trained relationship.

16. The method of claim 13, wherein the performing the inference operation includes:
generating dummy levelset data;
calculating dummy height data based on the function model information and the dummy levelset data;
determining whether an error of the dummy height data is in a tolerance range, based on the dummy height data and the target height data;
adjusting the dummy levelset data in response to determining that the error of the dummy height data is not in the tolerance range;
determining the dummy levelset data as target levelset data in response to determining that the error of the dummy height data is in the tolerance range; and
generating the target layout data based on the target levelset data.

17. A method of operating a semiconductor manufacturing system, which includes semiconductor manufacturing equipment and a computing device, the method comprising:
manufacturing, by the semiconductor manufacturing equipment, a semiconductor device by using a photomask corresponding to layout data;
measuring, by the semiconductor manufacturing equipment, height data of the semiconductor device;
providing, by the semiconductor manufacturing equipment, the layout data to the computing device;
providing, by the semiconductor manufacturing equipment, the height data to the computing device;
performing, by the computing device, a preprocessing operation based on the layout data and the height data to generate levelset data, the levelset data indicating an intensity of light passing through the photomask for each position in a distance direction; and
performing, by the computing device, a training operation based on the levelset data and the height data to generate function model information.

18. The method of claim 17, further comprising:
obtaining, by the computing device, target height data; and
performing, by the computing device, an inference operation based on the function model information and the target height data to generate target layout data.

19. The method of claim 18, further comprising:
providing, by the computing device, the target layout data to the semiconductor manufacturing equipment; and
manufacturing, by the semiconductor manufacturing equipment, a target semiconductor device by using a target photomask corresponding to the target layout data.

20. The method of claim 17, wherein
the photomask includes a bar pattern blocking the light or a space pattern passing the light, for each position in the distance direction,
the layout data have a first level value corresponding to the bar pattern or a second level value corresponding to the space pattern, for each position in the distance direction, and
wherein the levelset data includes
a reference level value at a first position of a boundary between the bar pattern and the space pattern,
a level value obtained by decreasing the reference level value by a bar level value at a second position corresponding to a center of the bar pattern, the bar level value being proportional to a width of the bar pattern, and
a level value obtained by increasing the reference level value as much as a space level value at a third position corresponding to a center of the space pattern, the space level value being proportional to a width of the space pattern.
